(19) United States
(12) Patent Application Publication
(10) Pub. No.: US 2012/0249894 A1
(43) Pub. Date: Oct. 4, 2012

(54) Television Apparatus and Electronic Device

(76) Inventor: Satoshi Azuchi, Tokyo (JP)

(21) Appl. No.: 13/278,951

(22) Filed: Oct. 21, 2011

(30) Foreign Application Priority Data
Mar. 31, 2011 (JP) 2011-079596

(51) Int. Cl. H04N 5/64; H05K 5/00

(52) U.S. Cl. 348/842; 361/679.01; 348/E05.129; 348/E05.132

(57) ABSTRACT

In one embodiment, a television apparatus comprises a display configured to include a screen, and a housing configured to store the display. The housing includes a first surface on which the screen is exposed, a second surface located on an opposite side of the first surface, a first end attachable to and detachable from a dock, a second end located on an opposite side of the first end, a third end connecting the first end and the second end, and a fourth end located on an opposite side of the third end, and include a first housing member having the first surface and a second housing member having the second surface. The apparatus further comprises a board including a first board surface facing toward the first surface and a second board surface facing toward the second surface, a sensor disposed on the first board surface, and a light-shielding member.

### CROSS REFERENCE TO RELATED APPLICATION

This application is based upon and claims the benefit of priority from the prior Japanese Patent Application No. 2011-79596, filed on Mar. 31, 2011, the entire contents of which are incorporated herein by reference.

### FIELD

Embodiments described herein relate to a television apparatus and an electronic device.

### BACKGROUND

Some television apparatuses include illuminance sensors for measuring illuminance of environment light.

If light in a housing of a television apparatus enters into an illuminance sensor, the sensor cannot accurately measure the illuminance of the environment light.

### BRIEF DESCRIPTION OF THE DRAWINGS

FIG. 1 is a perspective view showing an appearance of a television apparatus of a first embodiment;

FIGS. 2(A) to 2(F) are six surface views showing the appearance of the television apparatus of the first embodiment;

FIG. 3 is a rear view showing a structure of a first housing member;

FIG. 4 is a front view showing an internal configuration of the television apparatus of the first embodiment;

FIG. 5 is a rear view showing the internal configuration of the television apparatus of the first embodiment;

FIG. 6 is an enlarged front view showing the configuration near an illuminance sensor;

FIG. 7 is a cross-sectional view along an A-A line shown in FIG. 6;

FIG. 8 shows a modification of the cross-sectional view along the A-A line shown in FIG. 6;

FIG. 9 is a cross-sectional view along a B-B line shown in FIG. 6;

FIG. 10 is a front view showing an appearance of a stationary television apparatus; and

FIG. 11 is a perspective view showing an appearance of a notebook PC.

### DETAILED DESCRIPTION

Embodiments will now be explained with reference to the accompanying drawings.

An embodiment described herein is a television apparatus including a display configured to include a screen, and a housing configured to store the display, have a first surface on which the screen is exposed, a second surface located on an opposite side of the first surface, a first end attachable to and detachable from a dock, a second end located on an opposite side of the first end, a third end connecting the first end and the second end, and a fourth end located on an opposite side of the third end, and include a first housing member having the first surface and a second housing member having the second surface. The apparatus further includes a board stored in the housing, and having a first board surface facing toward the first surface and a second board surface facing toward the second surface , and a sensor disposed on the first board surface of the board, and having first to fourth side surfaces facing toward the first to fourth ends, respectively. The apparatus further includes a light-shielding member surrounding the first to fourth side surfaces of the sensor.

Another embodiment described herein is an electronic device including a housing, a board stored in the housing, a sensor disposed on the board. The device further includes a surrounding portion which surrounds the sensor, and is provided on an inner surface of the housing and spaced from the board, or is provided on the board and spaced from the inner surface of the housing.

### First Embodiment

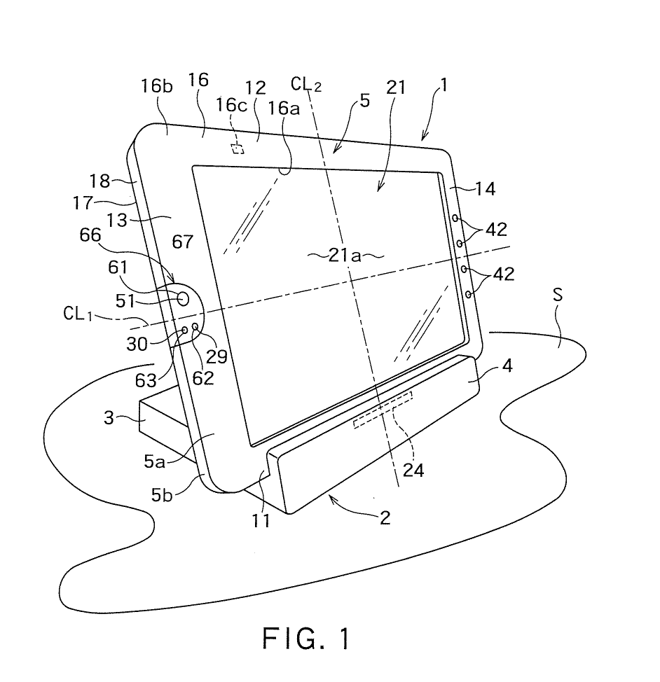

FIG. 1 is a perspective view showing an appearance of a television apparatus 1 of a first embodiment. The television apparatus 1 is a portable television apparatus, and is configured to be attachable to and detachable from a dock 2. The television apparatus 1 can be used while being mounted to the dock 2 or held by a user.

As shown in FIG. 1, the television apparatus 1 is mounted to the dock 2 to be held. The dock 2 has a main body 3 and a holding portion 4. The main body 3 has an external connecting terminal, for example, and a power supply part which supplies a power source to the television apparatus 1. In addition, the holding portion 4 is provided on the upper surface of the main body 3 and holds the television apparatus 1. The television apparatus 1 is held while being tilted, for example.

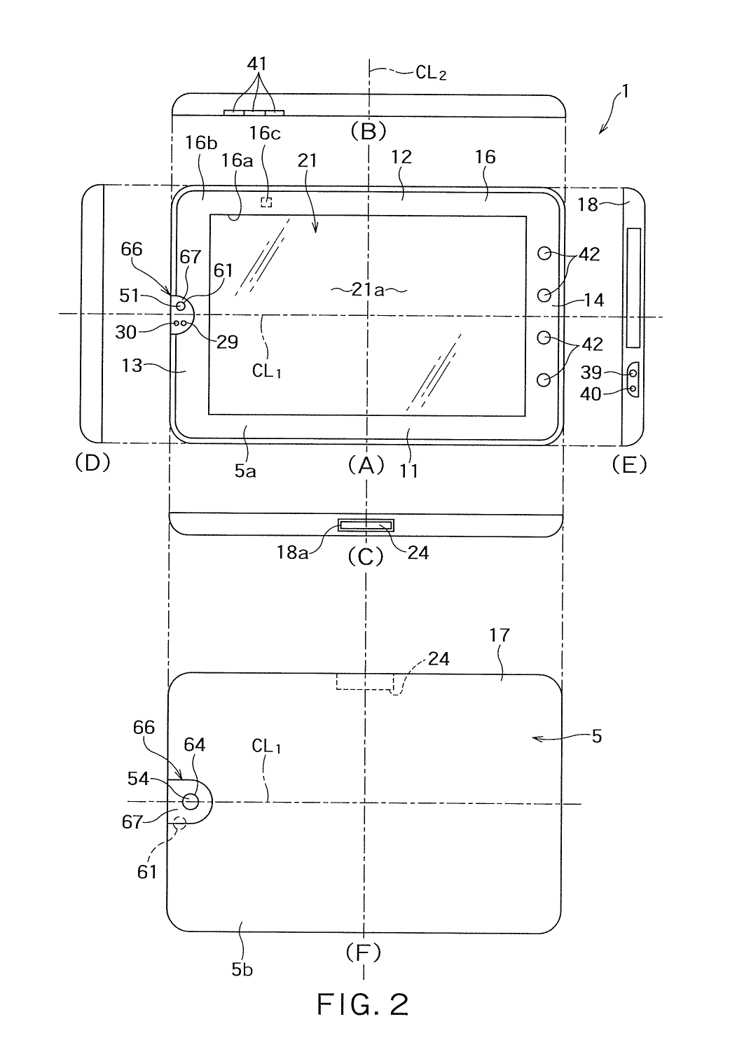

FIGS. 2(A) to 2(F) are six surface views showing the appearance of the television apparatus 1 of the first embodiment.

FIG. 2(A) is a front view of the television apparatus 1, and FIGS. 2(B), 2(C), 2(D), and 2(E) are a top view, a bottom view, a left side view, and a right side view of the television apparatus 1, respectively. In addition, FIG. 2(F) is a rear view of the television apparatus 1.

In the present specification, the up and down directions are defined based on the state in which a housing 5 is held by the dock 2 (see, FIG. 1). In addition, the left and right directions are defined based on a viewpoint of a user. Further, the side closer to the user is defined as the front side, and the side farther from the user is defined as the rear side.

As shown in FIGS. 2(A) to 2(F), the television apparatus 1 has the housing 5. The housing 5 is formed into a flat rectangular shape having rounded corners. The housing 5 has first to fourth ends 11, 12, 13, and 14.

The first end 11 is attachable to and detachable from the holding portion 4 of the dock 2. The second end 12 is located on the opposite side of the first end 11 and extends substantially parallel to the first end 11. Further, the third end 13 connects the first end 11 and the second end 12 with each other and extends in a direction substantially perpendicular to the first end 11. The fourth end 14 is located on the opposite side of the third end 13 and extends substantially parallel to the third end 13. As with the third end 13, the fourth end 14 connects the first end 11 and the second end 12 with each other.

The first and second ends 11 and 12 extend in a longitudinal direction of the housing 5. Meanwhile, the third and fourth ends 13 and 14 extend in a lateral direction of the housing 5 and are shorter than the first and second ends 11 and 12.

When the housing 5 is held by the dock 2 (see, FIG. 1), the first end 11, the second end 12, the third end 13, and the fourth end 14 are a lower end, an upper end, a left end, and a right end of the housing 5, respectively. When the housing 5 is held by the dock 2, the first and second ends 11 and 12 are substantially horizontal. Meanwhile, the third and fourth ends 13 and 14 are in a state of standing up with respect to a table top surface S.

As shown in FIGS. 2(A) to 2(F), the housing 5 has a front surface 16, a rear surface 17, and a peripheral surface 18. In addition, the housing 5 is provided with a first housing member 5a and a second housing member 5b. The front surface 16 is constituted of the first housing member 5a, and the rear surface 17 and the peripheral surface 18 are constituted of the second housing member 5b. In the present embodiment, the first housing member 5a is formed of glass, and the second housing member 5b is formed of a material other than glass (for example, plastic or metal).

The housing 5 stores a display 21 therein. The display 21 has a screen 21a on which an image is displayed. The screen 21a may have a touch panel having an input function. The front surface 16 of the housing 5 has an opening 16a, and the screen 21a is exposed through the opening 16a.

The rear surface 17 is located on the opposite side of the front surface 16. The size of the rear surface 17 is slightly smaller than the size of the front surface 16. The peripheral surface 18 has a curved surface shape, and connects a peripheral edge of the front surface 16 and a peripheral edge of the rear surface 17. The front surface 16, the rear surface 17, and the peripheral surface 18 are examples of a first surface, a second surface, and a third surface, respectively.

In the present embodiment, although the housing 5 has the four ends 11 to 14, the number of the ends of the housing 5 may be three or less or five or more. Further, the first and second ends 11 and 12 may extend in a non-parallel manner. Similarly, the third and fourth ends 13 and 14 may extend in a non-parallel manner.

Further, in the present embodiment, although the housing 5 has a planar structure having the front surface 16, the rear surface 17, and the peripheral surface 18, the housing 5 may have a planar structure other than the above structure.

Further, in the present embodiment, although the housing 5 is provided with two housing members 5a and 5b, the number of the housing members constituting the housing 5 may be only one or three or more.

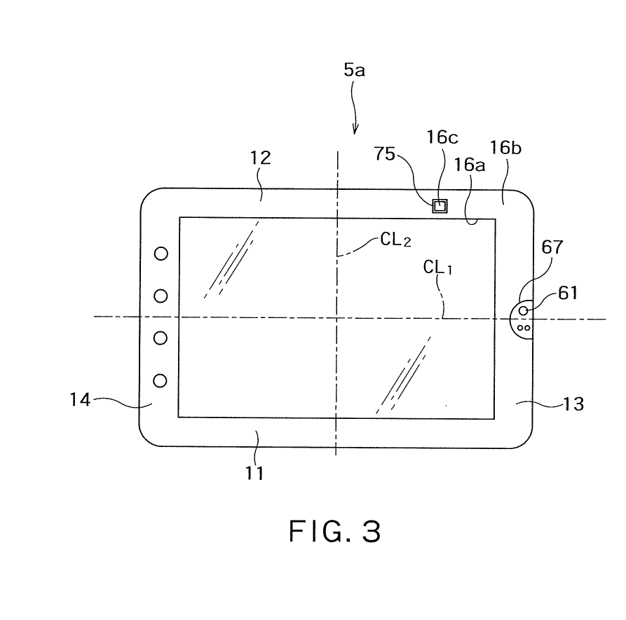

FIG. 3 is a rear view showing a structure of the first housing member 5a. FIG. 3 shows a state in which the front surface 16 is viewed from the rear side, that is, from a side of the rear surface 17.

The front surface 16 has the opening 16a, a light-shielding portion 16b surrounding the periphery of the opening 16a, and a light-transmission portion 16c provided in the light-shielding portion 16b.

The light-shielding portion 16b is formed by coating the rear surface of the first housing member 5a with a first coating material having light-shielding characteristics. Accordingly, the light-shielding portion 16b has a function of preventing environment light from outside of the housing 5 from entering inside the housing 5. The first coating material is black ink, for example. The light-shielding portion 16b is an example of a first region.

The light-transmission portion 16c is formed by coating the rear surface of the first housing member 5a with a second coating material, which is formed of a material different from the first coating material or has a concentration different from that of the first coating material. The light-transmission portion 16c is configured so that the environment light can transmit through the light-transmission portion 16c to such an extent that an illuminance sensor 71 to be described later can measure the illuminance of the environment light. However, if the color of the light-shielding portion 16b and the color of the light-transmission portion 16c are widely different from each other, the design properties of the television apparatus 1 are reduced. Therefore, it is desirable that the color of the second coating material is close to the color of the first coating material. The second coating material is, for example, black ink formed of a material different from the first coating material, or has a concentration different from that of the first coating material. The light-transmission portion 16c is an example of a second region.

The first and second coating materials may be coated on the front side (outer side) of the first housing member 5a. However, as in the present embodiment, it is desirable that the first and second coating materials are coated on the rear side (inner side) of the first housing member 5a. This is because if the first and second coating materials are coated on the front side of the first housing member 5a, these coating materials may be removed by a user holding the television apparatus 1.

As shown in FIG. 3, the first housing member 5a has, on its rear surface, a light-shielding member 75 surrounding the light-transmission portion 16c. The light-shielding member 75 is provided at a position surrounding the periphery of the illuminance sensor 71 to be described later. For example, the light-shielding member 75 is a glass member coated with the first coating material, and is molded with the first housing member 5a. The light-shielding member 75 is an example of a surrounding portion.

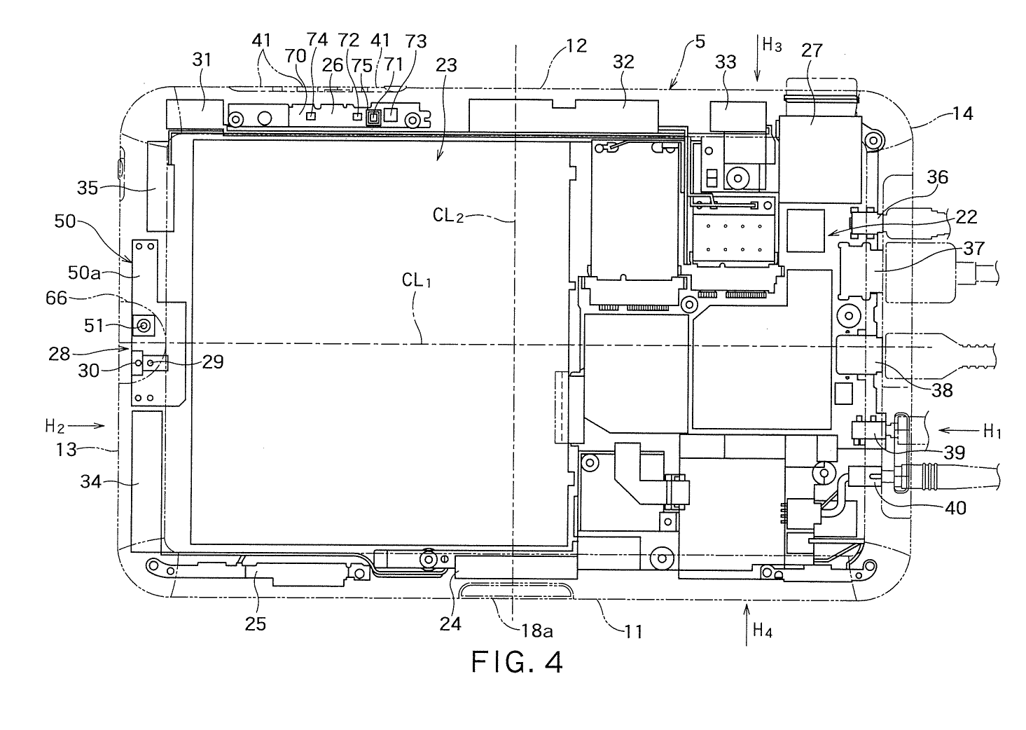

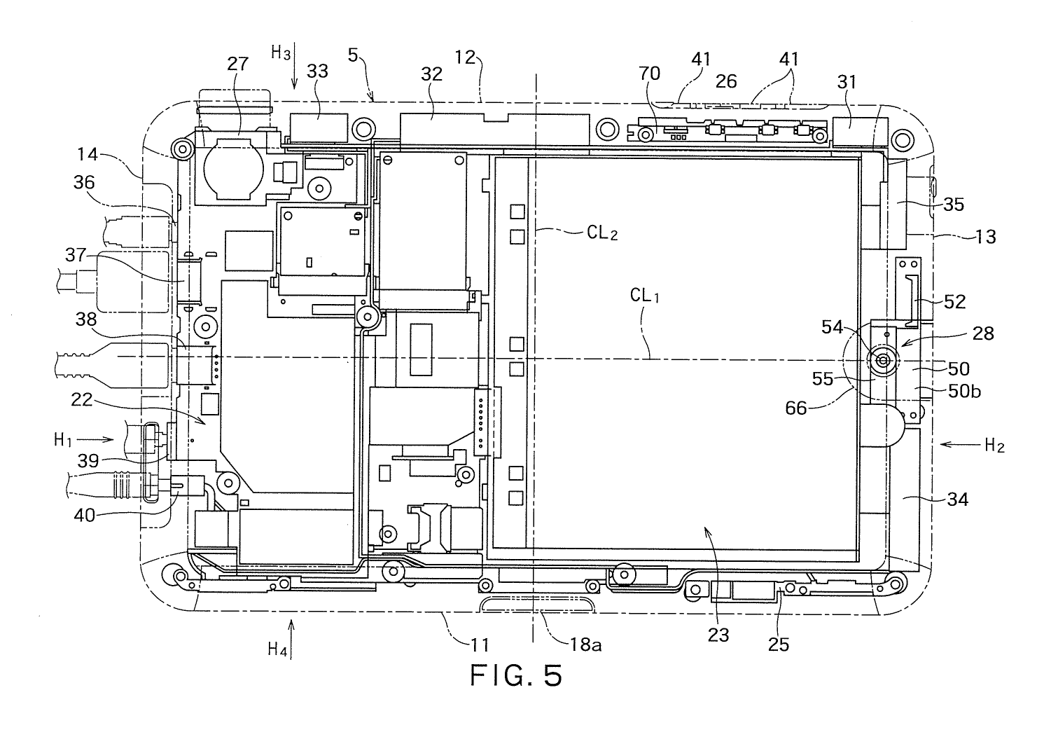

FIGS. 4 and 5 are a front view and a rear view showing an internal configuration of the television apparatus 1 of the first embodiment, respectively. The reference numeral CL₁. represents a center line between the first and second ends 11 and 12, and the reference numeral CL₂ represents a center line between the third and fourth ends 13 and 14.

When a user watches the television apparatus 1 while holding the television apparatus 1 in the hand, the user can watch the television apparatus 1 so that the first and second ends 11 and 12 are in a horizontal or vertical state.

In the former case, the first end 11, the second end 12, the third end 13, and the fourth end 14 are the lower end, the upper end, the left end, and the right end of the housing 5, respectively. In addition, in this case, it is assumed that the user generally holds a portion H₁ in the right hand and holds a portion H₂ in the left hand. The portion H₁ corresponds to a region of the fourth end 14 on the first end 11 side relative to the center line CL₁. Meanwhile, the portion H₂ corresponds to a region of the third end 13 on the first end 11 side relative to the center line CL₁.

Further, in the latter case, the first end 11, the second end 12, the third end 13, and the fourth end 14 are the left end, the right end, the upper end, and the lower end of the housing 5, respectively. In addition, in this case, it is assumed that the user generally holds a portion H₃ in the right hand and holds a portion H₄ in the left hand. The portion H₃ corresponds to a region of the second end 12 on the fourth end 14 side relative to the center line CL₂. Meanwhile, the portion H₄ corresponds to a region of the first end 11 on the fourth end 14 side relative to the center line CL₂.

As shown in FIGS. 4 and 5, the housing 5 stores a main circuit board 22, a battery 23, a docking connector 24, a vibration module 25, a switch module 26, a slot 27, a camera module 28, a microphone 29, a light emitting diode (LED) 30, a plurality of antennas 31, 32, 33, 34, and 35, and a plurality of connectors 36, 37, 38, 39, and 40.

The main circuit board 22 is located at a position close to the forth end 14 in the housing 5. Specifically, the main circuit board 22 is disposed so that the gravity center of the main circuit board 22 is located on the fourth end 14 side relative to the center line CL₂. This is because it is desirable that the main circuit board 22 is disposed near the fourth end 14 because the connectors 36 to 40 are disposed at the fourth end 14. A central processing unit (CPU) and other electronic components are mounted on the main circuit board 22.

Meanwhile, the battery 23 is disposed in a region close to the third end 13 in the housing 5. Specifically, the battery 23 is disposed so that the gravity center of the battery 23 is located on the third end 13 side relative to the center line CL₂. The reason is as follows. Namely, the sizes of the main circuit board 22 and the battery 23 are large, and therefore, when the main circuit board 22 is disposed in a region close to the fourth end 14, a region where the battery 23 can be disposed is limited to the region close to the third end 13.

The docking connector 24 is disposed at the first end 11 in the housing 5 and connected to a connector of the dock 2. In order to render the horizontal width of the screen 21a larger than the vertical width at the time of docking, the docking connector 24 is disposed at the first end 11 extending in the longitudinal direction of the housing 5. The housing 5 has on the peripheral surface 18 an opening 18a corresponding to the docking connector 24. The docking connector 24 is exposed outside the housing 5 through the opening 18a. The docking connector 24 is an example of a first connector.

The vibration module 25 is disposed at the first end 11 in the housing 5 and used when the television apparatus 1 is vibrated. Since sensors 71, 72, and 73 to be described later are disposed at the second end 12, the vibration module 25 is disposed at the first end 11 opposite to the second end 12. This constitution allows to prevent the vibration of the vibration module 25 from reducing the sensitivities of the sensors 71, 72, and 73.

The switch module 26 is disposed at the second end 12 in the housing 5. The switch module 26 has a circuit board 70 and a plurality of switches mounted on the circuit board 70. The housing 5 has on the peripheral surface 18 a plurality of buttons 41 corresponding to the switch module 26. When the buttons 41 are pressed, the television apparatus 1 receives various inputs.

The reason why the switch module 26 is disposed at the second end 12 is as follows. Namely, when the switch module 26 is disposed at the first end 11, there is an issue that the switch module 26 is hidden in the dock 2 at the time of docking. Further, since the camera module 28 and the connectors 36 to 40 are disposed at the third and fourth ends 13 and 14, there is an issue that it is difficult to secure the arrangement space of the switch module 26 at the third and fourth ends 13 and 14.

The switch module 26 is provided at the second end 12 and disposed on the third end 13 side relative to the center line CL₂. This is because if the switch module 26 is disposed on the fourth end 14 side relative to the center line CL₂, when a user holds the region H₃ in the right hand, the buttons 41 are get in the way of the user's hand. Note that when the switch module 26 is disposed at the second end 12, the user can operate the buttons 41 with the right hand when watching the television apparatus 1 while holding the regions H₃ and H₄.

The slot 27 is disposed at the second end 12 in the housing 5. Specifically, the slot 27 is provided at the second end 12 and disposed on the fourth end 14 side relative to the center line CL₂. The slot 27 is, for example, a memory card slot for an SD card (registered trademark). The slot 27 is mounted on the main circuit board 22.

The camera module 28 is disposed at the third end 13 in the housing 5 and mainly used when a user watches the television apparatus 1 while holding the regions H₃ and H₄. The reason why the camera module 28 is disposed at the third end 13 is because when the user watches the television apparatus 1 while holding the television apparatus 1, the user can easily take an image when the camera module 28 is provided at the upper end.

The camera module 28 is provided with a circuit board 50, a first camera 51, a first connector 52, a second connector 53, a second camera 54, and a flexible printed circuit board 55. The camera module 28 is further provided with, as shown in FIGS. 1 and 2(A) to 2(F), a first photographing hole 61, a sound collecting hole 62, a display hole 63, a second photographing hole 64, a camera part 66, and a decorative member 67. The microphone 29 and the LED 30 are disposed on the circuit board 50.

The antennas 31 to 33 of the antennas 31 to 35 are disposed at the second end 12 of the housing 5. In addition, the antennas 34 are disposed at the third end 13 of the housing 5. The antennas 31 to 35 are used respectively for W-LAN, 3G (third-generation mobile communication system), Bluetooth (registered trademark), 3G, and GPS. The camera module 28 is disposed between the two antennas 34 and 35 and disposed on the center line CL₁.

The connectors 36 to 40 are disposed at the fourth end 14 in the housing 5. Since the camera module 28 is disposed at the third end 13, the connectors 36 to 40 are disposed at the remaining fourth end 14. The connectors 36 to 40 are used respectively for MiniUSB, high-definition multimedia interface (HDMI), USB, audio, and power supply. The connectors 36 to 40 are mounted on the main circuit board 22. The connectors 36 to 40 are examples of a second connector.

The television apparatus 1 is further provided with a plurality of buttons 42 used for operating the television apparatus 1 (see, FIGS. 1 and 2(A) to 2(F)). The buttons 42 are arranged in the light-shielding portion 16b of the front surface 16 and disposed at the fourth end 14.

(1) Details of Sensors 71 to 73

Next, the sensors 71 to 73 will be described with reference to FIGS. 4 and 5.

As shown in FIGS. 4 and 5, the housing 5 further stores the illuminance sensor 71, the proximity sensor 72, the infrared sensor 73, an LED 74, and the light-shielding member 75. Those components 71 to 75 are arranged at the second end 12 in the housing 5, and disposed on the third end 13 side relative to the center line CL₂.

The illuminance sensor 71, the proximity sensor 72, the infrared sensor 73, and the LED 74 are arranged on the circuit board 70 for the switch module 26. Specifically, the circuit board 70 has a first board surface facing toward the front surface 16 and a second board surface facing toward the rear surface 17, and the components 71 to 74 are arranged on the first board surface.

The reason why the sensors 71 to 73 are disposed at the second end 12 is as follows. Namely, when the sensors 71 to 73 are disposed at the first end 11, there is an issue that the sensors 71 to 73 are hidden in the dock 2 at the time of docking. Further, since the camera module 28 and the connectors 36 to 40 are disposed at the third and fourth ends 13 and 14, there is an issue that it is difficult to secure the arrangement space of the circuit board 70 at the third and fourth ends 13 and 14.

In addition, the sensors 71 to 73 are provided at the second end 12, and disposed on the third end 13 side relative to the center line CL₂. This is because if the sensors 71 to 73 are disposed on the fourth end 14 side relative to the center line CL₂, the sensors 71 to 73 are hidden under the right hand of a user when the user holds the region H₃ in the right hand.

In addition, the sensors 71 to 73 are arranged on the first board surface of the first and second board surfaces of the circuit board 70. This is because since the illuminance sensor 71 and the infrared sensor 73 measure light transmitted through the first housing member 5a and infrared ray, respectively, it is inconvenient to arrange the sensors 71 to 73 on the second board surface.

In addition, the sensors 71 to 73 are arranged on the same board (circuit board 70) so as to approach each other. This is because if the sensors 71 to 73 are arranged to be away from each other, the holdable region is narrowly limited when the user holds the television apparatus 1.

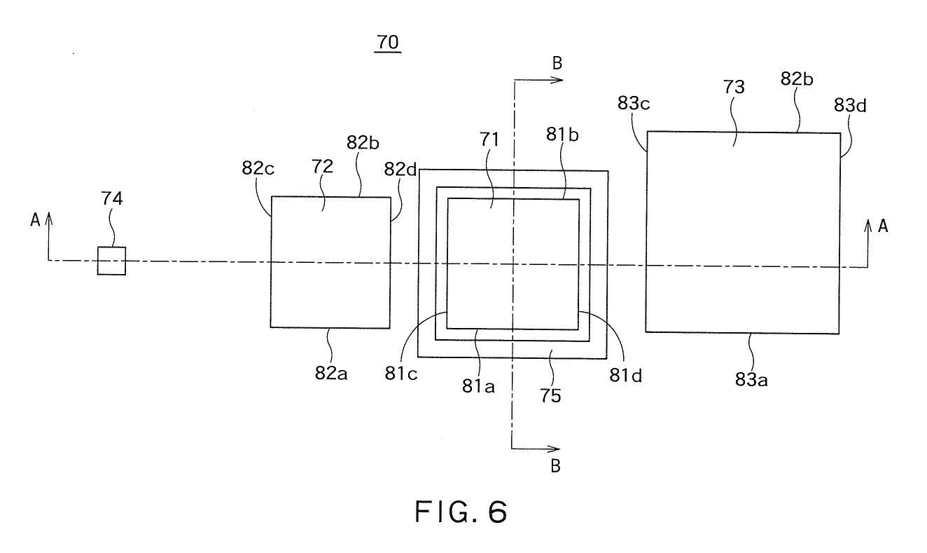

FIG. 6 is an enlarged front view showing the configuration near the sensors 71 to 73.

As shown in FIG. 6, the illuminance sensor 71 has first to fourth side surfaces 81a to 81d facing toward the first to fourth ends 11 to 14, respectively. In addition, the proximity sensor 72 has first to fourth side surfaces 82a to 82d facing toward the first to fourth ends 11 to 14, respectively. The infrared sensor 73 has first to fourth side surfaces 83a to 83d facing toward the first to fourth ends 11 to 14, respectively.

Each of the sensors 71 to 73 has a quadrangular planar shape. Further, the size of the planar shape of the infrared sensor 73 is designed to be larger than the sizes of the planar shapes of the illuminance sensor 71 and the proximity sensor 72.

The sensors 71 to 73 are arranged so that the positions of the first side surfaces 81a to 83a are equal to each other. Namely, the first side surfaces 81a to 83a are set so that the distances from the first end 11 are substantially equal to each other. Further, the sensors 71 to 73 are arranged so that the second side surface 83b of the infrared sensor 73 protrudes more outward than the second side surfaces 81b and 82b of the illuminance sensor 71 and the proximity sensor 72. Such an arrangement has an advantage that a possibility that the sensors 71 to 73 and the battery 23 are arranged to collide with each other can be reduced. This is because if the first side surface 83a of the infrared sensor 73 protrudes more outward than the first side surfaces 81a and 82a of the illuminance sensor 71 and the proximity sensor 72, the infrared sensor 73 is highly likely to collide with the battery 23.

Next, the positional relationship between the illuminance sensor 71 and the light-shielding member 75 will be described.

As shown in FIG. 6, the light-shielding member 75 is disposed so as to surround the first to fourth side surfaces 81a to 81d of the illuminance sensor 71. Accordingly, light from the inside of the housing 5 to the illuminance sensor 71 is blocked by the light-shielding member 75. Consequently, according to the present embodiment, the light from the inside of the housing 5 can be prevented from entering the illuminance sensor 71.

An example of the light from the inside of the housing 5 includes the light from the LED 74. Further examples thereof include the light from the display 21 and the LED 30 (see, FIG. 4). When the display 21 is a liquid crystal display (LCD), the light of an LCD backlight is included as an example.

In the present embodiment, the illuminance sensor 71 is surrounded by the light-shielding member 75 which is a surrounding portion having a light-shielding property. Similarly, the infrared sensor 73 may be surrounded by a surrounding portion for the infrared sensor 73, for example, by a surrounding portion having an infrared cut property. Similarly, the proximity sensor 72 may be surrounded by a surrounding portion for the proximity sensor 72. Further, in the present embodiment, although only the illuminance sensor 71 is surrounded by the single light-shielding member 75, the illuminance sensor 71, the proximity sensor 72, and the infrared sensor 73 may be collectively surrounded by the single light-shielding member 75.

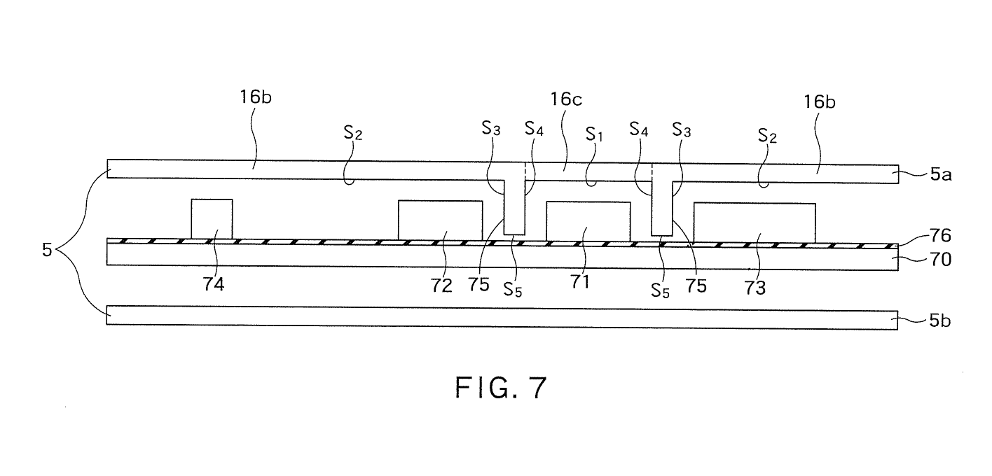

FIG. 7 is a cross-sectional view along an A-A line shown in FIG. 6.

FIG. 7 shows the light-shielding portion 16b and the light-transmission portion 16c of the first housing member 5a. The reference numeral S₂ represents the rear surface of the light-shielding portion 16b, and the reference numeral S₁ represents the rear surface of the light-transmission portion 16c. The rear surface S₂ of the light-shielding portion 16b is coated with the first coating material blocking the environment light. In addition, the rear surface S₁ of the light-transmission portion 16c is coated with the second coating material through which the environment light can be transmitted.

As shown in FIG. 7, the light-shielding member 75 is provided on the rear surface of the first housing member 5a so as to surround the light-transmission portion 16c. Further, the illuminance sensor 71 is disposed at a position facing the light-transmission portion 16c on the circuit board 70 and surrounded by the light-shielding member 75.

Accordingly, the illuminance sensor 71 is irradiated with the environment light from the outside of the housing 5 through the light-transmission portion 16c. Meanwhile, the light from the inside of the housing 5 to the illuminance sensor 71 is blocked by the light-shielding member 75. Consequently, according to the present embodiment, the illuminance sensor 71 can accurately measure the illuminance of the environment light.

The reference numeral S₄ represents the inner wall surface of the light-shielding member 75, that is, the surface on the illuminance sensor 71 side. The reference numeral S₃ represents the outer wall surface of the light-shielding member 75, that is, the surface opposite side of the illuminance sensor 71. Further, the reference numeral S₅ represents the bottom surface of the light-shielding member 75, that is, the surface on the circuit board 70 side.

In the present embodiment, the surfaces S₃ to S₅ of the light-shielding member 75 are coated with the first coating material. However, the bottom surface S₅ may not be coated. Further, any one of the inner wall surface S₄ and the outer wall surface S₃ may be coated with the first coating material. Further, the surfaces S₃ to S₅ of the light-shielding member 75 may be coated with a third coating material which is formed of a material different from the first coating material or has a concentration different from that of the first coating material, and has a light-shielding property.

Moreover, the light-shielding member 75 may be formed of the same material as the first housing member 5a, or a different material from the first housing member 5a. In the former case, the light-shielding member 75 can be easily manufactured by molding it with the first housing member 5a. Meanwhile, in the latter case, the light-shielding member 75 is adhered onto the rear surface of the first housing member 5a by an adhesive, for example. The latter case is mostly assumed when the light-shielding member 75 is coated with the third coating material. In the latter case, the entire light-shielding member 75 may be formed of a material having a light-shielding property.

In the present embodiment, although the illuminance sensor 71 that measures the illuminance of the environment light is surrounded by the light-shielding member 75, other light detection sensors may be surrounded by the light-shielding member 75. According to this constitution, the sensor can accurately detect light to be detected.

Next, the positional relationship between the light-shielding member 75 and the circuit board 70 will be described.

As shown in FIG. 7, the light-shielding member 75 is disposed on the first housing member 5a while being spaced from the circuit board 70. Namely, the bottom surface S₅ of the light-shielding member 75 is spaced from the upper surface (first board surface) of the circuit board 70.

The reason why the light-shielding member 75 is spaced from the circuit board 70 is as follows. In general, the first housing member 5a is formed of a material having a relatively high rigidity, and the circuit board 70 is formed of a material having a relatively low rigidity. Accordingly, when the light-shielding member 75 is in contact with the circuit board 70, the circuit board 70 is deformed, and the circuit board 70 may be damaged. Further, in a case where the light-shielding member 75 is formed of an electroconductive material, if the light-shielding member 75 is in contact with the circuit board 70, wirings on the circuit board 70 and the light-shielding member 75 may be short-circuited. Accordingly, in the present embodiment, the light-shielding member 75 and the circuit board 70 are spaced from each other, whereby those issues are avoided.

Further, as shown in FIG. 7, an insulating film 76 for protecting wirings is provided on the first board surface of the circuit board 70, and constitutes the first board surface. The bottom surface S₅ of the light-shielding member 75 faces the insulating film 76, and is spaced from the insulating film 76.

The reason why the light-shielding member 75 faces the insulating film 76, and is spaced from the insulating film 76 is as follows. Namely, the light-shielding member 75 and the insulating film 76 are spaced from each other in order to avoid deformation of and damage to the circuit board 70. Meanwhile, the reason why the light-shielding member 75 faces the insulating film 76 is because even when the light-shielding member 75 and the first board surface are temporarily in contact with each other due to, for example, the deformation of the first housing member 5a, the short-circuiting between the wirings on the circuit board 70 and the light-shielding member 75 can be prevented by the insulating film 76.

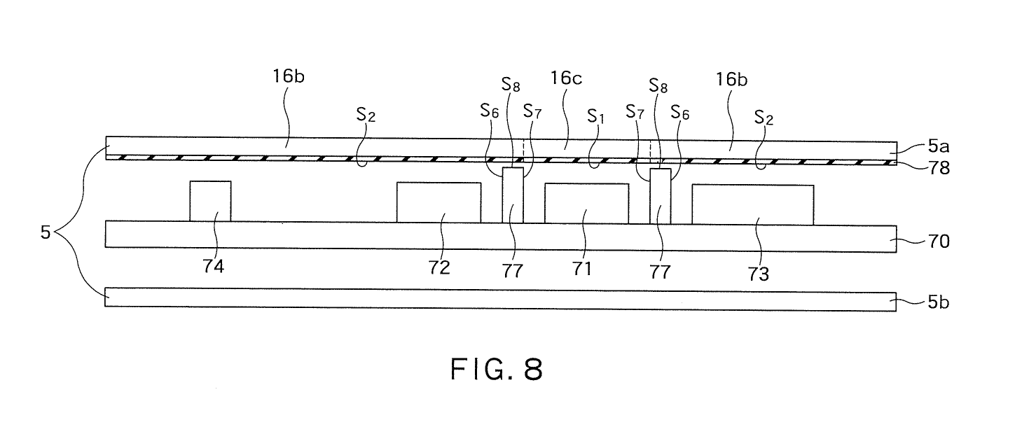

Note that the light-shielding member 75 may be disposed on the circuit board 70 instead of on the first housing member 5a. An example of such an arrangement of the light-shielding member 75 will be described with reference to FIG. 8.

(2) Modification of First Embodiment

Similarly to FIG. 7, FIG. 8 is a cross-sectional view along the A-A line shown in FIG. 6. However, in the FIG. 8, a light-shielding member is denoted by the reference numeral 77, and an insulating film is denoted by the reference numeral 78.

As shown in FIG. 8, the light-shielding member 77 is provided on the upper surface (first board surface) of the circuit board 70 so as to overlap the light-transmission portion 16c vertically. In addition, the illuminance sensor 71 is disposed at a position surrounded by the light-shielding member 77 on the circuit board 70 and faces the light-transmission portion 16c.

Accordingly, the illuminance sensor 71 is irradiated with the environment light from the outside of the housing 5 through the light-transmission portion 16c. Meanwhile, the light from the inside of the housing 5 to the illuminance sensor 71 is blocked by the light-shielding member 77. Consequently, according to the present embodiment, the illuminance sensor 71 can accurately measure the illuminance of the environment light.

The reference numerals S₆ and S₇ respectively represent the inner wall surface and the outer wall surface of the light-shielding member 77. Further, the reference numeral S₈ also represents the upper surface of the light-shielding member 77, that is, the surface on the first housing member 5a side. In the present embodiment, the surfaces S₆ and S₈ are coated with the first coating material.

Next, the positional relationship between the light-shielding member 77 and the first housing member 5a will be described.

As shown in FIG. 8, the light-shielding member 77 is disposed on the circuit board 70 while being spaced from the first housing member 5a. Namely, the upper surface S₈ of the light-shielding member 77 is spaced from the rear surface of the first housing member 5a. According to this constitution, as in the case of FIG. 7, the deformation of and the damage to the circuit board 70 are avoided.

Further, as shown in FIG. 8, the insulating film 78 for protecting the housing is provided on the rear surface of the first housing member 5a, and the insulating film 78 constitutes the rear surface of the housing. In addition, the upper surface S₈ of the light-shielding member 77 faces the insulating film 78, and is spaced from the insulating film 78. According to this constitution, as in the case of FIG. 7, the deformation of the circuit board 70 and the short-circuiting between the first housing member 5a and the light-shielding member 75 are prevented.

As described above, according to the configuration of FIG. 8, the advantages similar to those of the configuration of FIG. 7 can be obtained.

(3) Details of Component Arrangement on Circuit Board 70

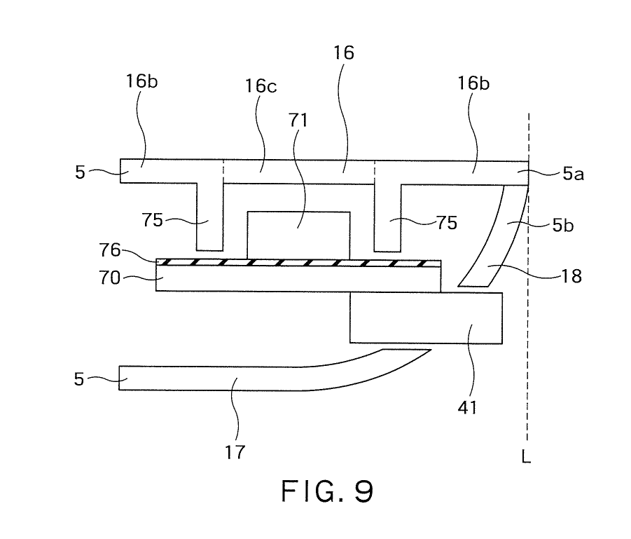

Next, details of the component arrangement on the circuit board 70 will be described with reference to FIG. 9. FIG. 9 is a cross-sectional view along a B-B line shown in FIG. 6.

As shown in FIG. 9, the circuit board 70 is disposed so that the lower surface (second board surface) is floated from the rear surface 17. More specifically, the circuit board 70 is disposed above the main circuit board 22, that is, the circuit board 70 is disposed so that the distance from the front surface 16 is small in comparison with the main circuit board 22. This constitution has such an advantage that components can be mounted on the lower surface of the circuit board 70 in addition to the upper surface of the circuit board 70. Moreover, there is such an advantage that the distance between the first housing member 5a and the illuminance sensor 71 is reduced, so that the illuminance sensor 71 can easily receive the environment light.

The reference numeral 41 represents a button mounted on the lower surface of the circuit board 70. The button 41 is disposed so as to pass through a hole provided in the peripheral surface 18 of the housing 5. A straight line L represents a position of the peripheral edge of the front surface 16. The button 41 is disposed so as not to protrude the outer side of the straight line L, that is, the outer side of the peripheral edge of the front surface 16. This is because when the button 41 protrudes the outer side of the straight line L, the button 41 is viewed from the direction of the front surface 16, so that the design properties are deteriorated. In other words, the button 41 is disposed so as to be contained inside the peripheral edge of the front surface 16.

Finally, the effects of the first embodiment will be described.

In the present embodiment, the light-shielding member 75 (or 77, and the same will be applied to the following description) is disposed so as to surround the illuminance sensor 71. Accordingly, the light from the inside of the housing 5 to the illuminance sensor 71 is blocked by the light-shielding member 75. Consequently, according to the present embodiment, the light from the inside of the housing 5 can be prevented from entering the illuminance sensor 71.

Further, in the present embodiment, the light-shielding member 75 is spaced from the circuit board 70 and disposed on the first housing member 5a, or the light-shielding member 75 is spaced from the first housing member 5a and disposed on the circuit board 70. Consequently, according to the present embodiment, it is possible to suppress the light-shielding member 75 from deforming and damaging the circuit board 70.

Further, in the present embodiment, the light-shielding member 75 faces the insulating film 76 (or 78, and the same will be applied to the following description) on the circuit board 70 or the first housing member 5a, and is spaced from the insulating film 76. Consequently, according to the present embodiment, even when the light-shielding member 75 and the circuit board 70 or the first housing member 5a are temporarily in contact with each other due to, for example, the deformation of the first housing member 5a, the short-circuiting between those components can be prevented by the insulating film 76.

In the present embodiment, although the sensors 71 to 73 are arranged on the first board surface of the circuit board 70, the sensors 71 to 73 may be arranged at other positions of the circuit board 70. For example, the sensors 71 to 73 may be disposed on the second board surface of the circuit board 70. In this case, the rear surface 17 or the peripheral surface 18 has the light-transmission portion 16c.

Hereinafter, for the second embodiment that is a modification of the first embodiment, the differences from the first embodiment will be mainly described.

### Second Embodiment

The first embodiment can be applied to an electronic device other than the television apparatus 1. In the second embodiment, examples of the electronic device will be described.

The examples of the electronic device of the present embodiment include a personal computer (PC), a portable telephone, a smartphone, a personal digital assistant (PDA), and a game machine. In addition, the examples of PC include a notebook PC and a slate PC. Further, the electronic device of the present embodiment may be a stationary television apparatus.

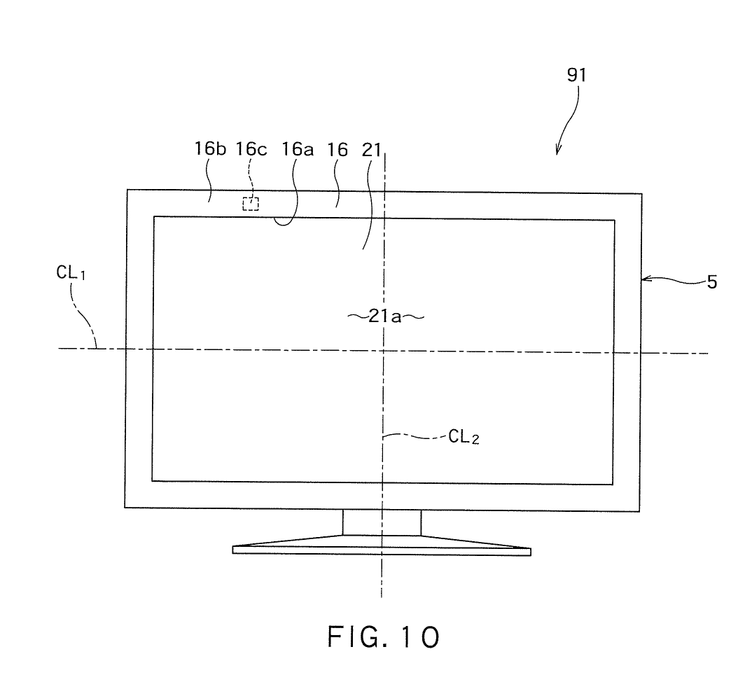

FIG. 10 is a front view showing an appearance of a stationary television apparatus 91.

FIG. 10 shows a housing 5 and a display 21 having a screen 21a. FIG. 10 further shows an opening 16a, a light-shielding portion 16b, and a light-transmission portion 16c of a front surface 16. The television apparatus 91 of FIG. 10 is an example of the electronic device of the present embodiment.

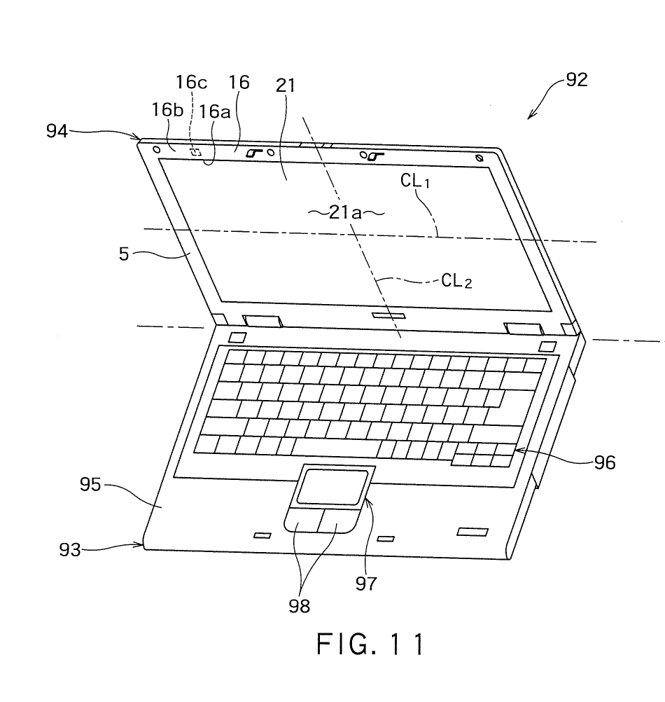

FIG. 11 is a perspective view showing an appearance of a notebook PC 92.

The PC 92 of FIG. 11 is provided with a first main body 93 and a second main body 94. In addition, the first main body 93 is provided with a housing 95, a keyboard 96, and a pointing device 97, and a click button 98. In addition, the second main body 94 is provided with a housing 5 and a display 21 having a screen 21a. FIG. 11 further shows an opening 16a, a light-shielding portion 16b, and a light-transmission portion 16c of a front surface 16. Similarly to the television apparatus 91 of FIG. 10, the PC 92 of FIG. 11 is an example of the electronic device of the present embodiment.

The present embodiment can be applied to an electronic device other than the above electronic devices as long as it includes a sensor that detects light, such as the illuminance sensor 71.

While certain embodiments have been described, these embodiments have been presented by way of example only, and are not intended to limit the scope of the inventions. Indeed, the novel apparatuses and devices described herein may be embodied in a variety of other forms; furthermore, various omissions, substitutions and changes in the form of the apparatuses and devices described herein may be made without departing from the spirit of the inventions. The accompanying claims and their equivalents are intended to cover such forms or modifications as would fall within the scope and spirit of the inventions.

1. A television apparatus comprising:
a display configured to comprise a screen;
a housing configured to store the display, have a first surface on which the screen is exposed, a second surface located on an opposite side of the first surface, a first end attachable to and detachable from a dock, a second end located on an opposite side of the first end, a third end connecting the first end and the second end, and a fourth end located on an opposite side of the third end, and comprise a first housing member having the first surface and a second housing member having the second surface;
a board stored in the housing, and having a first board surface facing toward the first surface and a second board surface facing toward the second surface;
a sensor disposed on the first board surface of the board, and having first to fourth side surfaces facing toward the first to fourth ends, respectively; and
a light-shielding member surrounding the first to fourth side surfaces of the sensor.

2. The apparatus of claim 1, wherein
the light-shielding member is disposed on the first housing member, and spaced from the board.

3. The apparatus of claim 2, wherein
a surface of the light-shielding member facing toward the board is configured to face an insulating film provided on the first board surface of the board, and is spaced from the insulating film.

4. The apparatus of claim 1, wherein
the light-shielding member is disposed on the board, and spaced from the first housing member.

5. The apparatus of claim 4, wherein
a surface of the light-shielding member facing toward the first housing member is configured to face an insulating film provided on a surface of the first housing member on the board side, and is spaced from the insulating film.

6. The apparatus of claim 1, wherein a surface of the first housing member on the board side comprises:
a first region coated with a first coating material; and
a second region coated with a second coating material which is formed of a material different from the first coating material, or has a concentration different from a concentration of the first coating material,
wherein the sensor is disposed at a position facing the second region.

7. The apparatus of claim 1, wherein the sensor is disposed at the second end.

8. The apparatus of claim 7, further comprising a vibrator disposed at the first end.

9. The apparatus of claim 7, further comprising a camera disposed at the third end,
wherein the sensor is disposed on the third end side compared to a center line between the third and fourth ends.

10. An electronic device comprising:
a housing;
a board stored in the housing;
a sensor disposed on the board; and
a surrounding portion which surrounds the sensor, and is provided on an inner surface of the housing and spaced from the board, or is provided on the board and spaced from the inner surface of the housing.
